(19) United States
(12) Patent Application Publication
(10) Pub. No.: US 2003/0079342 A1
(43) Pub. Date: May 1, 2003

(54) Conductor wire manipulator, machine and insertion method incorporating said manipulator

(76) Inventors: Jean Revel, Pourriere (FR); Claudio Meisser, Cham (CH)

Correspondence Address: MACMILLAN SOBANSKI & TODD, LLC, ONE MARITIME PLAZA FOURTH FLOOR, 720 WATER STREET, TOLEDO, OH, 43604-1619, US

(21) Appl. No.: 10/283,504

(22) Filed: Oct. 30, 2002

(30) Foreign Application Priority Data
Oct. 31, 2001 (EP) 01811057.7

(51) Int. Cl. H05K 13/00; H01R 43/00; B23P 19/00

(52) U.S. Cl. 29/854; 29/857; 29/747; 29/33 F

(57) ABSTRACT

A wire manipulator includes a body with a jack for moving clamping arms to hold a wire extremity insert the extremity in an alveolus of a connector. The insertion force is sensed by a force sensor in the clamping arms and is compared with a reference force to stop the insertion process to avoid damage to the wire, the connector and the manipulator.

### BACKGROUND OF THE INVENTION

The present invention relates to a wire manipulator, a method for inserting an extremity of a conductive wire section in an alveolus on a connector, and an insertion machine incorporating the manipulator.

The technical sphere of the invention concerns the production of automatic machines for preparing bundles of electric cables. The U.S. Pat. No. 5,615,478 describes various types of pliers for manipulating electrically conductive wire sections and the integration of the latter in a wire bundle preparation machine, as well as a method and a device for inserting wire extremities in connector alveoli or similar electric components.

The EP 902 509 patent document shows a system for controlling the quality of crimping of a cable eye stiffener at the extremity of an electric wire section which makes use of a force sensor comprising two piezoelectric ceramic disks, the force sensor being mounted on a crimping press between a crimping tool support and a slide driven in an alternative movement of translation by a rotary motor equipped with a cam so that the sensor is sensitive to the crimping force exerted by the press on the cable eye stiffener to be crimped.

The use of this type of force sensor generally requires calibration so as to be able to compensate any observed defects of precision and linearity, which complicates the practical use of these sensors. This drawback is particularly sensitive in a case where it is desired to measure the force of inserting a wire extremity in an alveolus, given the fact that an insertion manipulator operates on extremely small series of identical successive insertions and frequently an insertion manipulator successively provokes the insertions of extremities provided with different cable eye stiffeners for which different insertion forces need to be controlled. On the other hand, a crimping press generally carries out a large number of identical crimping operations.

Piezoelectric ceramic sensors, whose sensitivity is about one or several hundreds of pico coulomb/Newtons, if they are adapted to measuring a crimping force—which is generally more than 2000 Newtons—are ill-adapted to measuring an insertion force—which is generally situated inside a range of between 1 and 100 Newtons.

In addition, the short response time of this type of dynamic force sensor renders it sensitive to the inertia forces resulting from the established accelerations of the mobile elements of the crimping press to which it is linked. Now the search for high operating rates provokes significant accelerations and as a result significant inertia forces which interfere with the measurement to be made.

The signals delivered by the piezoelectric sensors are in addition frequently disturbed when the elements—such as connectors or conductive wires—for connecting the sensor to an electronic device for processing the signals delivered by the sensor—such as a load amplifier—are subjected to movements. In fact, these movements can generate parasitic electric loads, particularly via a triboelectric effect. This is the reason it is awkward to use these sensors mounted on mobile machine elements and assumes particular importance since the results of the force measurement are used as a criterion for evaluating the quality of the operation (or insertion) concerned.

### SUMMARY OF THE INVENTION

The aim of the manipulator and method according to the present invention is to provide these improved clamps, methods and insertion devices.

One objective of the present invention is to provide a reliable inexpensive system for the systematic control of the quality for inserting a wire in an alveolus of a component when the extremity of the wire has been previously rendered integral—by crimping or other means—with possibly a cable eye stiffener. After a large number of ineffective attempts, it has been surprisingly found that in accordance with the apparatus and method of the present invention it is possible to use this type of sensor to measure the insertion force of a wire extremity in an alveolus of a connector with sufficient measurement reliability so that the results of this measurement are used to control insertion quality.

According to one characteristic of the present invention, a wire manipulator is provided comprising a body and a wire support element mounted mobile with respect to the body in which the wire support element comprises a sensor sensitive to a force exerted by this element.

The present invention concerns in particular a clip for inserting an extremity of a conductive wire into the alveolus of a connector which comprises a body and an arm equipped with a clamping jaw for holding the wire and mounted mobile with respect to the body in which the arm comprises a piezoelectric sensor for measuring an insertion force.

Because the sensor is integrated in the mobile element of the clip (of the manipulator) and is accordingly situated at the closest to the wire section gripping jaws, the sensitivity of the sensor to the force required to insert the extremity in an alveolus is increased, whereas the sensitivity of the sensor to the parasitic forces resulting in particular from the inertia effects and the mechanisms for moving and opening the clip (of the manipulator) is at the same time reduced.

The sensor preferably comprises two washers—or thin plate or disk-shaped pieces—made of a polarised ceramic material which are identical, mounted side by side and compression-prestressed between two parallel faces of two pieces forming part of the arm or manipulator. This makes it possible to embody a simple compact sensor in which each washer is sensitive to the compression forces of the washer and the axial extension forces of the washer, this thus making it possible to measure an insertion force (conventionally positive), as well as an opposite direction (and sign) force. This then makes it possible to measure a traction force exerted on the wire after it has been inserted so as to ensure that the insertion is correctly and fully effected, especially in the case of insertion in an alveolus of a cable eye stiffener equipped with locking tongues.

So as to favor the sensitivity of the sensor to forces exerted along an axis distinct from the median axis of the two sensitive elements, a mounting is preferably provided in opposition to the latter. Thus, the sensitivity of the sensor to forces moved out of centre (by reference to this median axis) is increased, especially to forces exerted close to a longitudinal extremity of the arm or wire support element which result in a torque—or moment—applied to the sensor.

It is advantageous to carry out this mounting in opposition by having the two sensitive elements head-to-tail and by providing an equipotential conductor on each of the faces of the pieces surrounding the sensitive elements, a first equipotential connecting the positive pole of a first element sensitive to the negative pole of a second sensitive element, and a second equipotential connecting the negative pole of said first sensitive element to the positive pole of said second sensitive element, each equipotential being preferably respectively connected by a coaxial conductor to one input of a charge amplifier which converts the charge variations of the sensor into a voltage or current, this making in particular it possible to reduce the number of electric connections upstream of the amplifier and accordingly to limit disturbances of the measuring signal likely to result from a stray current resulting from these connections.

Alternatively, in certain cases, it is possible to provide this mounting in opposition for adding the sensitivities of the two sensitive elements without inverting the polarities of the two elements placed side by side. However, in this case, additional electric connections need to be provided.

Moreover, in the case where the insertion axis was merged with the median axis of the sensitive elements, the mounting in opposition would be replaced by a mere placing in parallel or even a single sensitive element could be used.

By using sensitive elements pierced with a central orifice (washer-shaped), it is possible to provide an elongated linking element such as a screw, which extends through the orifice, is used to fix all the portions of the arm or support element extending on both sides of the sensor, and which is also used to stress the sensitive element. So as to allow the sensitive element to dilate, for this linking element, it is recommended to select a material and a section so that the stiffness of this link is clearly less than the stiffness of the sensitive element. This can in particular be embodied by a screw or steel rod whose section is smaller than the support surface (and/or the cross section) of the washer, this linking element then forming a return spring during an axial extension of one of the sensitive elements of the sensor resulting from the application of a moved out of center force on the arm (or wire support element).

When the clamp or manipulator comprises two arms or wire support elements which are generally mounted mobile with respect to the body—it is preferable to equip each of them with a force sensor. Thus, by adding the measuring signals, this makes it possible to increase the sensitivity of the unit and also, via an OR operation replacing summing and applied to the two measuring signals to benefit from a redundancy of the sensors increasing the reliability of the insertion control system. In addition, the use of several sensitive elements, in particular at least three or four sensitive elements, makes it possible by means of differential measurements to determine several components of the force and thus make it possible to determine its direction.

So as to limit the disturbances of the signal for measuring the insertion force resulting from accelerations of the clamp or manipulator, it is important that that the weight of the portion “suspended from the sensor” of the arm of support element is as light as possible, and in addition to this effect, it is advantageous to bring the centre of gravity of this portion close to the median axis of the sensitive elements until they are made to coincide, if possible.

So as to limit disturbances of the measuring signal resulting from deformations of the cable connecting the sensor to an amplifier (charge converter/voltage or current), it is preferable to have this amplifier close to the sensor, especially on the body of the clamp or manipulator.

In addition it is to be noted that, in an insertion method according to the invention, measuring and control is made in real time during the insertion of a cable eye stiffener or wire extremity in an alveolus of a connector, the force transmitted by at least one portion of an arm or support element of the cable eye stiffener, and when it is detected that the measuring result departs by a reference outside a predetermined maximum deviation range, an order is given to stop an element from moving the clamp or the manipulator so as to stop the insertion procedure, which avoids damaging the connector and/or the cable eye stiffener.

Said piezoelectric ceramic sensor is preferably used whose output is connected to a load amplifier and the input and/or output of the amplifier is reset to zero before each insertion operation so as to eliminate any residual charges likely to result from the preceding insertion operation and/or likely to result from one or several movements for grasping or approaching the cable eye stiffener or wire extremity.

For a plurality of successive insertion operations, it is preferable to record a plurality of insertion force data measured for each operation in or on a data storage of a computer so as to calculate and/or have available statistical data representative of insertion quality and its time evolution.

According to another characteristic of the invention, the machine for inserting cable eye stiffeners or wires in connector alveoli comprises:

a clamp or manipulator according to the invention;

a connector support(s);

at least one activator so as to move the clamp (the manipulator) towards a connector fixed on said connector support; and

means to control the movement of the clamp (of the manipulator) by the activator according to a force measuring signal delivered by the sensor integrated in the clamp (manipulator).

### DESCRIPTION OF THE DRAWINGS

The above, as well as other advantages of the present invention, will become readily apparent to those skilled in the art from the following detailed description of a preferred embodiment when considered in the light of the accompanying drawings in which:

FIG. 1 is a schematic perspective view of an insertion machine in accordance with the present invention;

FIG. 2 is an enlarged perspective view of the clamp (manipulator) shown in FIG. 1;

FIG. 3 is an exploded perspective view of the clamp shown in FIG. 2;

FIG. 4 is a front elevation view of the clamp shown in FIGS. 2 and 3 with two arms ended at their lower extremity by clamping jaws or jaws for seizing a wire section;

FIG. 5 is a side elevation view of the clamp shown in FIGS. 2 to 4 showing a load amplifier connected to the force sensor by a conductive wire;

FIG. 6 is a graph illustrating the variations of the insertion force (on the ordinate) according to the relative position (on the abscissa) measured along an insertion axis of the extremity of a wire section (or cable eye stiffener crimped to this extremity) with respect to an alveolus of a connector;

FIG. 7 is a schematic view of a clamp similar to that shown in FIGS. 2 to 5 with the mounting of two washers made of a piezoelectric ceramic material between the portions of an arm of the clamp; and

FIG. 8 is a circuit schematic illustrating the main components of the means for measuring a force via the processing of signals delivered by two pairs of piezoelectric elements respectively integrated with the two mobile arms of a clamp, such as the one shown in FIGS. 2 to 7.

### DESCRIPTION OF THE PREFERRED EMBODIMENT

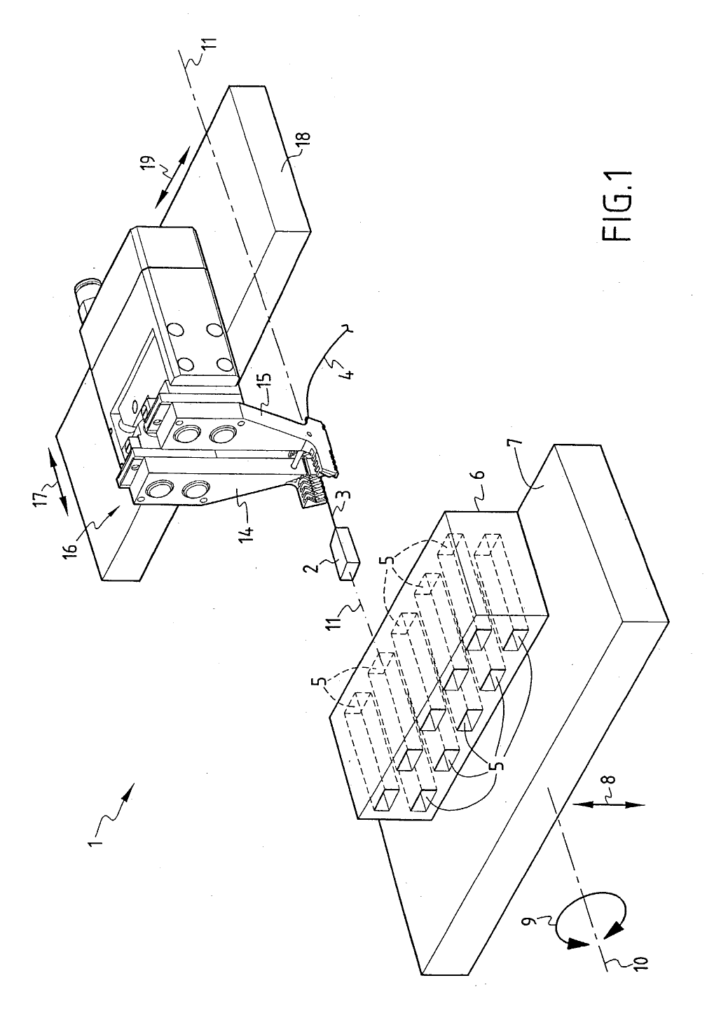

With reference in particular to FIG. 1, an insertion machine 1 has been specially designed so as to insert a cable eye stiffener 2 crimped at an extremity 3 of a wire section 4 (partially shown) in one of the alveoli 5 of a connector 6.

To this effect, the machine 1 includes a connector support 7 mounted mobile with respect to a base (not shown) according to a vertical movement of translation direction shown by an arrow 8 and a movement of rotation shown by a double-headed arrow 9 along a spindle axis 10, the spindle axis 10 being parallel to longitudinal axes of the alveoli 5. The insertion of the cable eye stiffener 2 in the alveolus 5 is effected via an insertion movement by translation along the longitudinal axis of this alveolus, such as an axis 11.

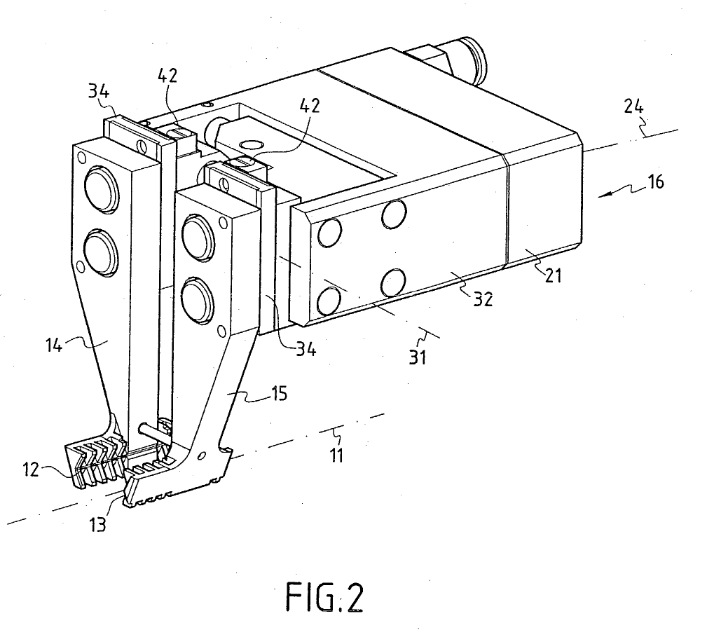

To this effect, the cable eye stiffener 2 and the extremity 3 are kept approximately aligned during this insertion movement with the alveolus axis 11 by a pair of jaws 12 and 13 (FIG. 2) respectively provided at lower extremities of a pair of arms 14 and 15 of a wire manipulator such as an insertion clamp 16 which jaws squeeze the extremity 3.

The insertion results from a movement indicated by a double-headed arrow 17 along the axis 11 of the clamp 16 holding the wire. To this effect, the clamp is mounted mobile with respect to a clamp support 18 along this direction 17 and along a direction indicated by a double-headed arrow 19 orthogonal to the directions 8 and 17.

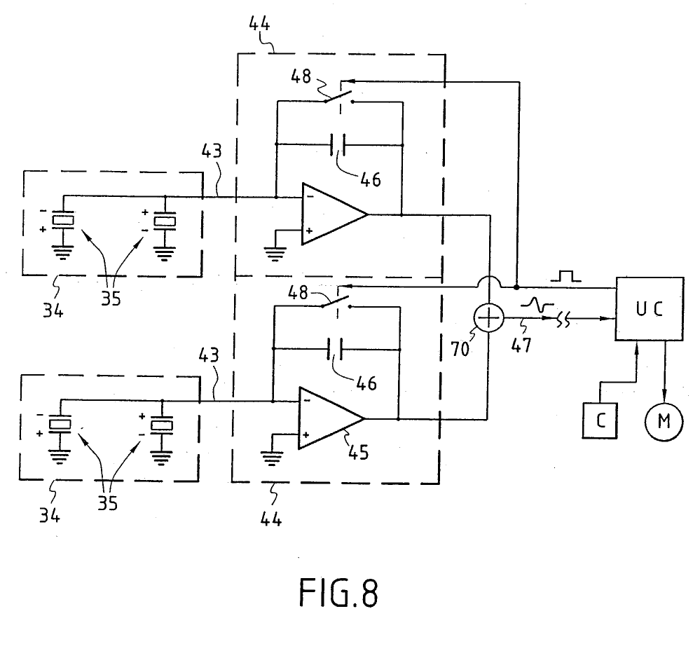

So as to ensure that the force for inserting the cable eye stiffener in the alveolus remains within predetermined limits, the movement 17 for bringing closer together the clamp 16 and the connector 6 under the action of a activator (such as a motor M shown in FIG. 8) is carried out under the control of an electronic signal and data processing unit (UC shown in FIG. 8) according to firstly force measuring signals and secondly signals for measuring the position of the clamp along the axis 11 delivered to the unit UC by a position sensor C (FIG. 8).

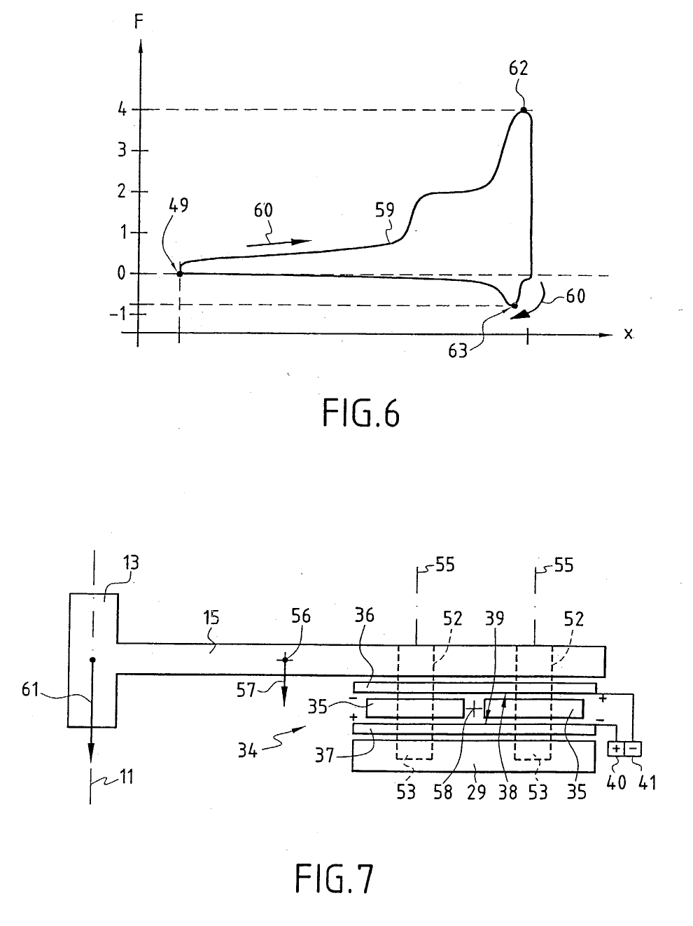

To this effect, the unit UC may comprise a memory (or other data support) in which for each type of alveolus/cable eye stiffener pairing a plurality of data is recorded corresponding to force nominal values (reference) or ranges of force nominal values in the form of tables or graphs, such as the one shown in FIG. 6, with which the force measurements are compared during an insertion cycle. These force nominal values can be obtained by the force measurement made by the sensor integrated with the clamp by means of “trial and error” during the preparatory cycles carried out in conditions representative of the actual insertion conditions.

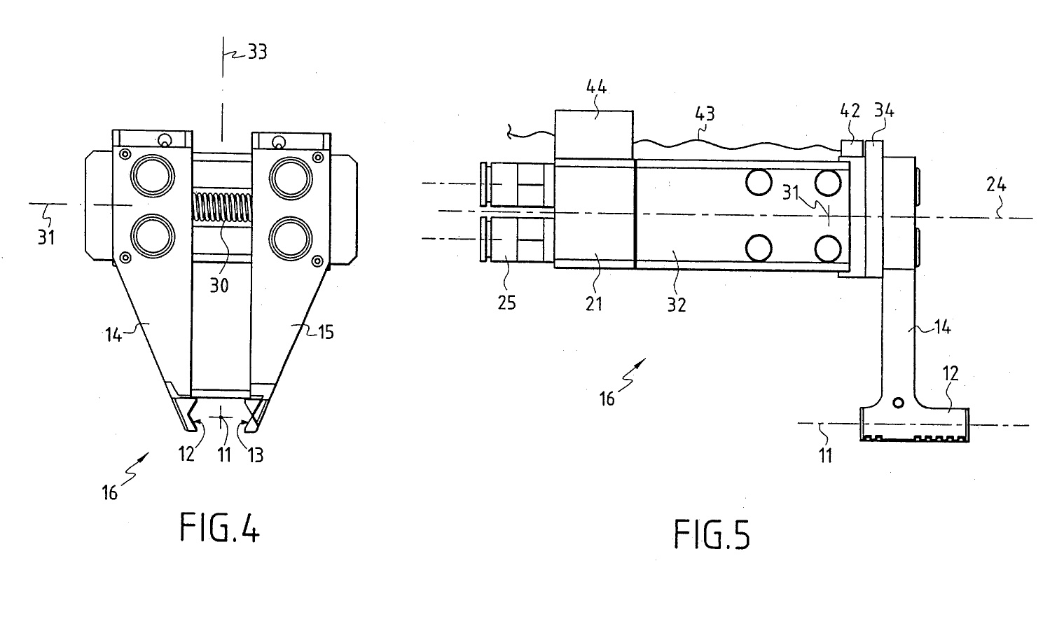

The wire manipulator or clamp 16 (FIGS. 2 to 5 and 7) comprises a body 20 having two portions: a rear portion 21 and a front portion 32. The rear portion 21 forms a hollow body (cylinder) of a jack used for closing the jaws 12 and 13 of the clamp. To this effect, the portion 21 has formed therein a bore 22 in which a piston 23 is mounted sliding along a longitudinal axis 24 of the body 20 and of the clamp 16. This axis 24 is parallel to the axis 11 according to which the jaws 12 and 13 squeeze the extremity 3 of the wire 4. Two couplings 25 connect this jack to a pneumatic compressed air feed circuit (not shown). A longitudinal extremity 26 of the piston 23 is profiled so as to form two cams 27 respectively supported on two blocks 28 and 29 respectively connected with the two mobile arms 14 and 15 of the clamp 16. A return spring 30 extending along an axis 31 keeps the blocks 28 and 29 spaced from each other when the pneumatic jack 22 and 23 has not been activated. The front portion 32 of the body 20, which is rigidly fixed to the rear portion 21, shelters the front portion of the piston 23 and supports a spindle shaft (not shown) coaxial with the axis 31 and orthogonal to the axis 24 on which the blocks 28 and 29 are mounted sliding so as to enable the jaws 12 and 13 to be brought together or moved apart under the action of the jack 22 and 23 and of the spring 30.

As shown in particular in FIGS. 2 to 4, the clamp 16, and in particular its elements 14, 15, 28 and 29 move in translation along the spindle axis 31 and are approximately symmetrical with respect to a median longitudinal plane 33.

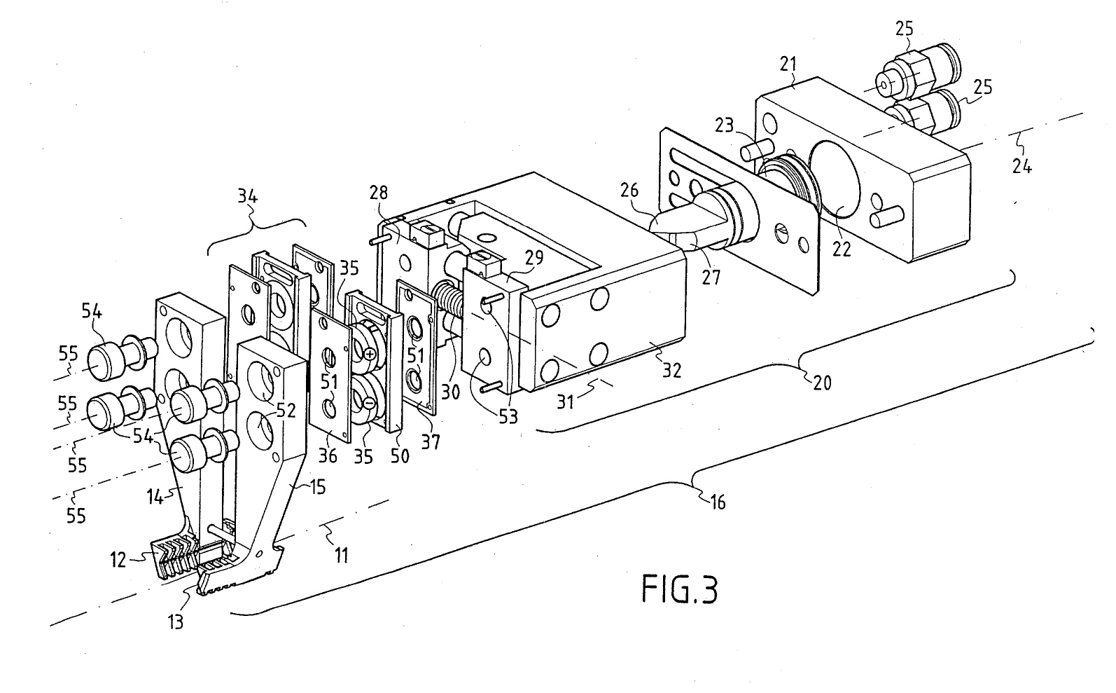

With reference in particular to FIGS. 3 and 7, the clamp 16 has two mobile wire clamping units each including one of the arms 14 and 15, one of the sliding blocks 28 and 29 respectively, and a force sensor 34 inserted and stretched between the arm and the associated sliding block.

Each of the sensors 34 comprises two identical ring-shaped elements 35 embodied in a lead titanate and zirconate-based ceramic material. An electrode is formed on each of the two annular flat faces of each element 35 corresponding to the positive pole and negative pole of the polarised element.

Each sensor 34 also comprises two approximately identical rectangular plates 36 and 37. Each plate is in support on two coplanar electrodes respectively provided on the annular faces of the two elements 35. The plates are at least in part embodied in an electrically nonconducting material, and an electrically conductive coating is provided on an internal face 38 and 39 of each plate 36 and 37 respectively so as to form an equipotential connecting the electrodes of the elements on which these equipotentials rest. Each plate 36 and 37 and its equipotential can be embodied in the form of a printed circuit.

Each equipotential is respectively connected to a connection terminal 40 and 41 of a terminal unit 42 (FIG. 5) of the sensor 34. A coaxial cable 43 connects these terminals to the inputs of a load amplifier 44 fixed to the rear portion 21 of the body 20 of the clamp 16 (FIG. 5).

Each sensor 34 further comprises an intermediate plate 50 (FIG. 3) pierced with two orifices through which the washers extend, this plate forming with the plates 36 and 37 a box containing the two sensitive elements. The plates 36 and 37 are each pierced with two orifices 51 whose center distance corresponds to that of the two elements 35 whereas each arm 14 and 15 is pierced with two orifices 52 separated by the same center distance and that each block 28 and 29 includes two tapped holes 53, also separated by the same center distance.

This construction allows the respective joining of each arm 14 and 15 to one of the blocks 28 and 29 by two screws 54 each with an axis 55.

The head of each screw 54 takes support on the arm 14 or 15. Each screw 54 extends through one of the orifices 52 in one of the arms 14 and 15, through one of the orifices 51 in one of the plates 36 and 37, and through the central orifice of one of the elements 35. Each screw 54 is threadably engaged in one of the tapped holes 53. During tightening of the screws 54, each element 35 is sandwiched between the plates 36 and 37, tightened between their faces 38 and 39, and the plates are also gripped tightly between the arm 14 and the block 28 or the arm 15 and the block 29 respectively.

Each of the load amplifier modules 44, FIG. 8, includes an amplifier 45 and a capacitor 46 connected between a negative input and an output of the amplifier. The negative input of the amplifier 45 is connected to the negative terminal 41 (FIG. 7) of the sensor 34, whereas the positive input is connected to the positive terminal 40 of the sensor and to the circuit ground potential. This mounting forms an integrator delivering at the output a voltage proportional to the cumulative total of the load variations of the two sensitive elements 35 placed head-to-tail between, the plates 36 and 37.

This output voltage from each of the load amplifiers 44 is summed together at a signal summer 70 and the summed voltage is delivered to the unit UC by a cable 47.

A reed switch 48 or an FET transistor is connected to the terminals of the capacitor 46 in parallel therewith. Closing of the switch 48 (normally open) is controlled by a signal delivered by the unit UC before each insertion operation so as to restore to zero the output of the integrator which corresponds to a point 49 on the graph of FIG. 6.

The functioning of the equipment according to the present invention is as follows: the approach of the cable eye stiffener 2 with respect to an alveolus 5 is carried out by the actuator M. Owing to the cumulated weight of the cable eye stiffener 2, the wire extremity 3 and the arm 14 or 15 which weight is suspended from each sensor 34, this results in accelerating an inertia force, indicated by an arrow 57 in FIG. 7, being applied to the center of gravity of the system suspended from the sensor, which is generally close to a center of gravity 56 (FIG. 7) of the arm 15 (or 14). Given the fact that this force is applied outside the portion of the plane of FIG. 7 that extends between the two axes 55 of the sensitive elements, the latter are stressed differentially. The first element 35 situated on the left in FIG. 7 is compressed, whereas the second element 35 (situated on the right in FIG. 7) of the same sensor is “relieved”, that is its compression stress (along its axis 55) is reduced. This force in the direction 57 results in an intimate movement in rotation of the arm 15 and the plate 36 with respect to the plate 37 and the block 29 by virtue of the elasticity of the screws 54 connecting them together. This minimum rotation of amplitude is effected approximately along an axis 58 orthogonal to the plane of FIG. 7.

The variations of the compression forces applied to the two elements 35 under the effect of this force 57, which are applied in an opposite direction, provoke load variations of contrary directions which, by means of the head-to-tail mounting of the polarities of the elements 35, are added which facilitates the detection and measurement of the force by the force measuring means (44, UC). This force corresponds to a portion of the graph of FIG. 6 that extends between the point 49 and a point 59 which is in a direction indicated by an arrow 60, the point 59 corresponding approximately to the contact between the cable eye stiffener 2 and the walls of the alveolus 5.

The actual insertion of the cable eye stiffener 2 in the alveolus 5 requires in particular a sufficient force be applied so as to overcome the rubbing of the cable eye stiffener against the walls of the alveolus, as well as generally the forces required to warp the cable eye stiffener and/or the walls of the alveolus. This results in a force, indicated by an arrow 61 in FIG. 7, being applied to the clamping jaws of each arm of the clamp approximately along the wire holding axis 11 in the same direction as the inertia force indicated by the arrow 57. The insertion force 61 provokes in the same way explained earlier for the force 57 a differential stressing of the two elements 35 of each of the sensors 34 which results in a force signal, such as the one corresponding to the portion of the graph of FIG. 6 extending between the point 59 and a point 62. When the cable eye stiffener 2 is completely inserted, the forward movement of the clamp is stopped and during the backward movement, the insertion force is cancelled. If appropriate, a force of an opposite direction (traction) is effected on the wire so as to test the resistance to tearing of the mechanical link between the inserted cable eye stiffener and the alveolus receiving it, which corresponds to the portion of the graph of FIG. 6 extending between the point 62 and a point 63 where the force is negative. The jaws 12 and 13 of the clamp 16 are then spaced from each other so as to free the wire extremity 3 via the action of the jack 22 and 23 and then the clamp 16 is moved backwards so as to revert to its initial position which corresponds to the portion of the graph of FIG. 6 that extends between the points 63 and 49.

In accordance with the provisions of the patent statutes, the present invention has been described in what is considered to represent its preferred embodiment. However, it should be noted that the invention can be practiced otherwise than as specifically illustrated and described without departing from its spirit or scope.

What is claimed is:

1. A wire manipulator for inserting a extremity of a wire into an alveolus of a connector comprising:
a body;
a clamping means for holding a wire adjacent an extremity of the wire, said clamping means being movably mounted on said body; and
a sensor means mounted in said clamping means for sensing an insertion force exerted as the extremity of the wire is inserted into an alveolus of a connector.

2. The wire manipulator according to claim 1 wherein said clamping means includes a pair of arms each equipped with a clamping jaw for holding the wire, said arms being mounted on said body for relative movement of said arms toward and away from each other.

3. The wire manipulator according to claim 2 wherein said arms are mounted for sliding movement and said body includes a jack for moving said arms away from each other.

4. The wire manipulator according to claim 1 wherein said sensor means includes a piezoelectric sensor for measuring the insertion force.

5. The wire manipulator according to claim 1 wherein said sensor means includes a pair of elements made of a polarized ceramic material tightly mounted between two relatively movable parts of said clamping means.

6. The wire manipulator according to claim 5 wherein said elements are placed head-to-tail between said parts so as to form a mounting in opposition.

7. The wire manipulator according to claim 1 wherein said sensor means senses a torque resulting from an application of a force exerted at a point on said clamping means spaced from said sensor means.

8. The wire manipulator according to claim 1 wherein said sensor means generates a signal representing the insertion force and including an amplifier connected to said sensor means and responsive to said signal, said amplifier being mounted on said body.

9. The wire manipulator according to claim 1 wherein said sensor means has an orifice formed therein and including a fastener extending through said orifice and being attached to said clamping means, said fastener compressing said sensor means and resiliently resisting expansion of said sensor means.

10. The wire manipulator according to claim 1 wherein said clamping means includes two arms, said sensor means includes a force sensor mounted at each of said arms, said force sensors each generating a signal representing the insertion force at an associated one of said arms, and including a signal summer for adding said signals from said force sensors.

11. A wire manipulator for inserting a extremity of a wire into an alveolus of a connector comprising:
a body including a jack;
a clamping means for holding a wire adjacent an extremity of the wire, said clamping means including a pair of opposed arms slidably mounted on said body and a return spring, said arms being movable to an open position by said jack and to a closed position by said return spring;
a sensor means mounted in said clamping means for sensing an insertion force exerted as the extremity of the wire is inserted into an alveolus of a connector; and
means for moving said body and said clamping means in an insertion direction and being responsive to said sensor means for stopping movement in the insertion direction when said insertion force exceeds a predetermined amount.

12. The wire manipulator according to claim 11 including a wire engaging jaw attached to each said arm.

13. The wire manipulator according to claim 11 wherein said sensor means includes two polarized ceramic sensitive elements compressed between faces of two plates.

14. The wire manipulator according to claim 11 wherein said sensor means includes a force sensor mounted on each said arm and a pair of elongated elastic fasteners extending along axes approximately parallel to an axis of the insertion direction and compressing said force sensors.

15. The wire manipulator according to claim 1 wherein said means for moving includes a motor coupled to said clamping means and a data processing unit connected to said motor and to said sensor means, said data processing unit being responsive to a signal from said sensor means representing the insertion force for controlling said motor to move said clamping means.

16. A method for inserting an extremity of a wire in an alveolus of a connector with the aid of a manipulator comprising the steps of:
a. holding an extremity of a wire between a pair of clamping arms;
b. inserting the wire extremity into an alveolus of a connector;
c. sensing an insertion force at the clamping arms with a force sensor during said step b.; and
d. halting said step b. when the insertion force exceeds a predetermined reference force.

17. The method according to claim 16 including performing said step c. with a piezoelectric ceramic sensor having an output connected to an amplifier and resetting one of an input and output of said amplifier to zero before beginning said step b.
